(19) United States
(12) Patent Application Publication
(10) Pub. No.: US 2011/0303536 A1
(43) Pub. Date: Dec. 15, 2011

(54) SPUTTERING APPARATUS WITH MAGNETIC MODULE

(75) Inventor: CHUNG-PEI WANG, Tu-Cheng (TW)

(73) Assignee: HON HAI PRECISION INDUSTRY CO., LTD., Tu-Cheng (TW)

(21) Appl. No.: 13/149,883

(22) Filed: May 31, 2011

(30) Foreign Application Priority Data
Jun. 10, 2010 (TW) 99118826

(51) Int. Cl. C23C 14/34; C23C 16/48

(52) U.S. Cl. 204/298.16; 118/723 FI; 118/623

(57) ABSTRACT

An exemplary sputtering apparatus includes a chamber, a rotatable rack, a gate, two first magnetic elements, and a second magnetic element. A sidewall of the chamber has an opening defined therein. The rotatable rack is provided in a center of the chamber. The gate is provided in the opening. The two first magnetic elements are mounted on the gate. The second magnetic element is mounted inside the chamber. The second magnetic element neighbors one of the two first magnetic elements. A first angle is defined between two imaginary lines running from the rack to each of the two first magnetic elements. A second angle is defined between an imaginary line running from the rack to the second magnetic element and the imaginary line running from the rack to said one of the two first magnetic elements neighboring the second magnetic element. The first angle and the second angle are different.

### BACKGROUND

1. Technical Field

The disclosure relates generally to coating technologies, and more particularly to a sputtering apparatus.

2. Description of the Related Art

During a typical sputtering process, a plurality of workpieces are placed in a vacuum chamber. Energized ion bombardment vaporizes a solid source material. The vaporized material is deposited on the workpieces as a film. However, the effectiveness or efficiency of formation of the film coated on the workpieces may not always be satisfactory.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is a schematic, isometric view of a coating device in accordance with a first embodiment of the disclosure.

FIG. 2 is a cross-sectional view of the coating device of FIG. 1, taken along line II-II thereof.

FIG. 3 is an enlarged view of part of FIG. 2, showing a first mode of distribution of first magnetic elements and second magnetic elements of the coating device.

FIG. 4 is similar to FIG. 3, but showing a second mode of distribution of first magnetic elements and second magnetic elements of the coating device.

FIG. 5 is a schematic, cross-sectional view of a coating device in accordance with a second embodiment of the disclosure.

### DETAILED DESCRIPTION

The disclosure is illustrated by way of example and not by way of limitation in the figures of the accompanying drawings. It should be noted that references to “an” or “one” embodiment in this disclosure are not necessarily to the same embodiment, and such references can mean at least one.

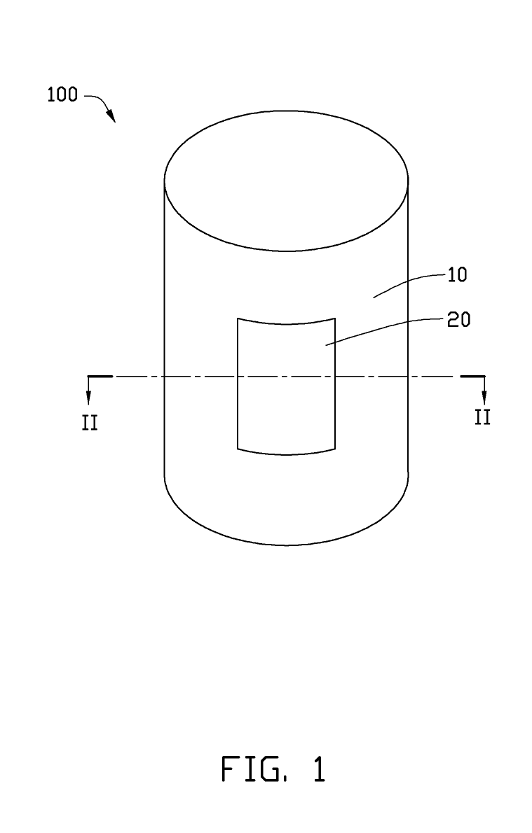

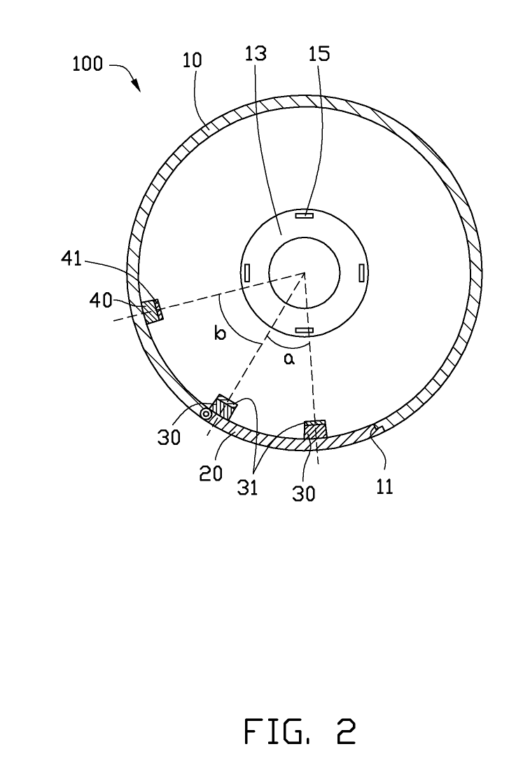

Referring to FIGS. 1-2, a sputtering apparatus 100 in accordance with a first embodiment of the disclosure includes a chamber 10, a gate 20, two first magnetic elements 30, and a second magnetic element 40.

The chamber 10 is cylindrical, and a vacuum is formed therein by vacuum pump evacuation.

A rack 13 is mounted in the center of the chamber 10. The rack 13 is circular, and rotatable about a center axis of the chamber 10. An opening 11 is defined in a cylindrical sidewall of the chamber 10. The gate 20 matches the opening 11. Targets and workpieces can be received in the chamber 10 through the opening 11. A plurality of supporting assemblies 15 is mounted on the rack 13. The supporting assemblies 15 are configured for holding the workpieces. Each of the supporting assemblies 15 defines a central axis (not shown) thereof. Each of the supporting assemblies 15 is rotatable about the central axis thereof. The supporting assemblies 15 are also rotatable about the center axis of the chamber 10 in unison with rotation of the rack 13.

The first magnetic elements 30 and the second magnetic element 40 are mounted to partially surround the rack 13. The first magnetic elements 30 are mounted on the gate 20. A first holder 31 is mounted on each of the two first magnetic elements 30. The first holders 31 are configured for holding targets (not shown). The targets of the first holders 31 of the two first magnetic elements 30 face the rack 13. The second magnetic element 40 is mounted on the sidewall of the chamber 10. A second holder 41 is mounted on the second magnetic element 40, and configured for holding a target (not shown).

An inner surface of the gate 20 is curved to correspond to the curvature of the sidewall of the chamber 10. Thus the distance between the rack 13 and each of the two first magnetic elements 30, and the distance between the rack 13 and the second magnetic element 40, are all uniform.

A first angle “a” is defined between two imaginary lines drawn from a center axis of the rack 13 to centers of the two first magnetic elements 30. The center axis of the rack 13 coincides with the center axis of the chamber 10. A second angle “b” is defined between an imaginary line drawn from the center axis of the rack 13 to a center of the second magnetic element 40, and the imaginary line drawn from the center axis of the rack 13 to the center of the first magnetic element 30 neighboring the second magnetic element 40. In the embodiment, the first angle “a” is 35°, and the second angle “b” is 45°.

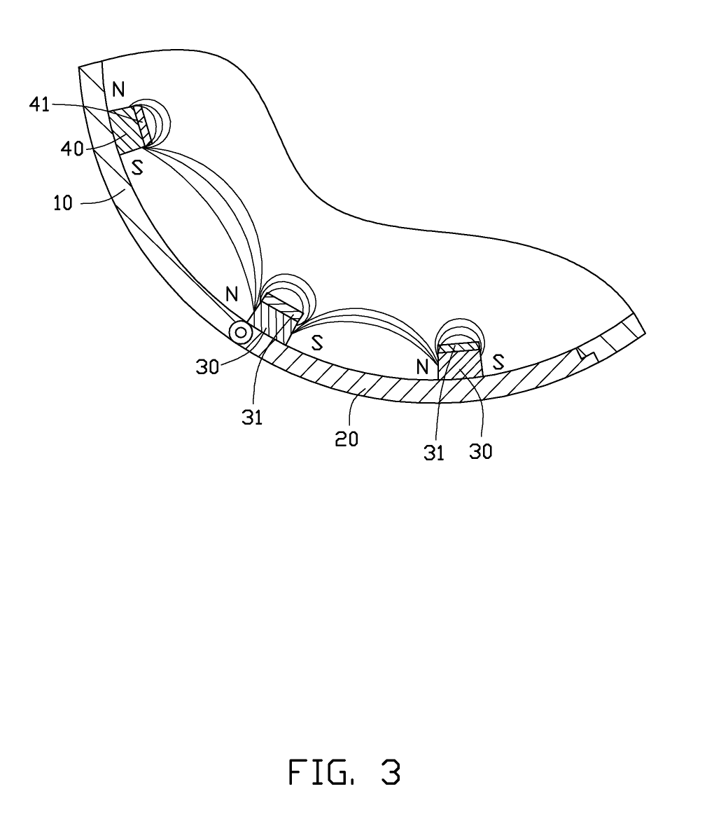

Optimally, the magnetic poles of the first magnetic elements 30 and the second magnetic element 40 are arranged in the same orientation relative to the gate 20 or the portion of the sidewall of the chamber 10 on which the first and second magnetic elements 30, 40 are respectively located. Such an arrangement shown in FIG. 3, wherein the North pole of each of the first and second magnetic elements 30, 40 is at the clockwise side of the first or second magnetic element 30, 40, and the South pole of each of the first and second magnetic elements 30, 40 is at the counterclockwise side of the first or second magnetic element 30, 40. With such arrangement, a continuous magnetic field is generated, and the strength of the magnetic field is increased.

Thus, the ion density and ionization rate in the chamber 10 are optimized, as is the coating efficiency. Different targets of different materials can be utilized to form different types of films on the workpieces.

In the embodiment, the first magnetic elements 30 and the second magnetic element 40 are solenoids or permanent magnets. In either case, the first and second magnetic elements 30, 40 have the same size. In alternative embodiments, the sizes of two first magnetic elements 30 may be different from the size of the second magnetic element 40. When the first and second magnetic elements 30, 40 are permanent magnets, the first and second magnetic elements 30, 40 may be made of the same material. Alternatively, the material of the first magnetic elements 30 may be different from the material of the second magnetic element 40.

Materials and sizes of the targets held by the first holder 31 and materials and sizes of the target held by the second holder 41 can be uniform or non-uniform. Thus, films of different materials and colors can be coated on the workpieces.

Referring to FIG. 3, each two nearest neighboring magnetic poles of opposite polarity along a circumferential direction of the gate 20 and the sidewall of the chamber 10 belong to the one solenoid 30 or 40 or the one permanent magnet 30 or 40. Each two distant neighboring magnetic poles of opposite polarity along the circumferential direction of the gate 20 and the sidewall of the chamber 10 belong to two adjacent solenoids 30 and 30/40 or two adjacent permanent magnets 30 and 30/40.

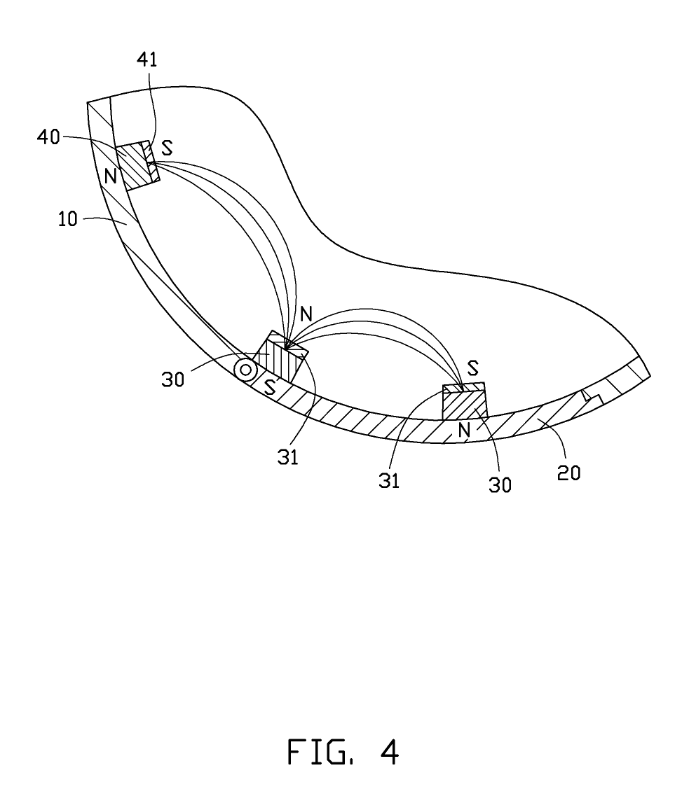

Referring to FIG. 4, in this alternative configuration, each two neighboring magnetic poles of opposite polarity along the circumferential direction of the gate 20 and the sidewall of the chamber 10 belong to two adjacent solenoids 30 and 30/40 or two adjacent permanent magnets 30 and 30/40.

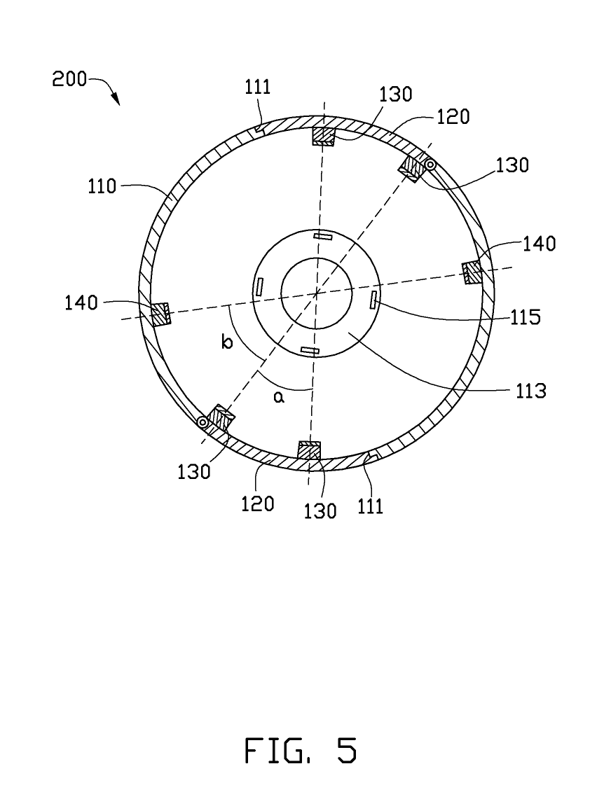

Referring to FIG. 5, a sputtering apparatus 200 in accordance with a second embodiment of the disclosure differs from the sputtering apparatus 100 only in that the sputtering apparatus 200 includes two openings 120, four first magnetic elements 130, and two second magnetic elements 140.

Two gates 111 are respectively provided in the two openings 120, with each gate 111 matching the corresponding opening 120. In the illustrated embodiment, the two gates 111 are radially symmetrical relative to each other across the center axis of the chamber 10. Two of the first magnetic elements 130 are mounted on one of the gates 111, and the other two first magnetic elements 130 are mounted on the other gate 111. Each of the second magnetic elements 140 is mounted on a portion of a cylindrical sidewall of a chamber 110 which neighbors a corresponding gate 111.

A plurality of supporting assemblies 115 is mounted on a rack 113. A first angle “a” is defined between two imaginary lines drawn from a center axis of the rack 113 to centers of the two first magnetic elements 130 on a given one of the gates 111. A second angle “b” is defined between an imaginary line drawn from the center axis of the rack 113 to a center of a given one of the second magnetic elements 140, and the imaginary line drawn from the center axis of the rack 113 to the center of the first magnetic element 130 neighboring the given second magnetic element 140. In the embodiment, the first angle “a” is 35°, and the second angle “b” is 45°.

While various examples and embodiments have been described, it is to be understood that the disclosure is not limited thereto. To the contrary, the disclosure is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A sputtering apparatus comprising:
a chamber comprising a sidewall having an opening defined therein;
a rotatable rack provided in a center of the chamber; and
a gate provided in the opening of the sidewall of the chamber; and
at least two first magnetic elements and at least one second magnetic element mounted inside the chamber at a circumferential periphery of the chamber;
wherein the at least one second magnetic element neighbors one of the at least two first magnetic elements;
a first angle is defined between two imaginary lines running from a center axis of the rack to a center of each of two of the at least two first magnetic elements;
a second angle is defined between an imaginary line running from the center axis of the rack to a center of one of the at least one second magnetic element and the imaginary line running from the center axis of the rack to the center of one of the two of the at least two first magnetic elements neighboring the one of the at least one second magnetic element; and
the first angle and the second angle are different from each other.

2. The sputtering apparatus of claim 1, wherein the first angle is approximately 35° and the second angle is approximately 45°.

3. The sputtering apparatus of claim 2, wherein sizes of the at least two first magnetic elements are different from a size of the at least one second magnetic element, and the materials of the at least two first magnetic elements are different from the material of the at least one second magnetic element.

4. The sputtering apparatus of claim 1, wherein sizes of the at least two first magnetic elements and the at least one second magnetic element are the same, and the at least two first magnetic elements and the at least one second magnetic element are made of the same material.

5. The sputtering apparatus of claim 1, wherein the at least two first magnetic elements and the at least one second magnetic element are solenoids or permanent magnets.

6. The sputtering apparatus of claim 1, further comprising a plurality of supporting assemblies mounted on the rack, wherein each of the supporting assemblies defines a central axis thereof, each of the supporting assemblies is rotatable about the central axis thereof, and the supporting assemblies are rotatable in unison with the rack.

7. The sputtering apparatus of claim 1, wherein the at least two magnetic elements and the at least one second magnetic element are mounted to substantially surround the rack.

8. The sputtering apparatus of claim 1, wherein the chamber is a vacuum chamber.

9. The sputtering apparatus of claim 1, wherein the at least two first magnetic elements are two first magnetic elements and the at least one second magnetic element is a second magnetic element, the two first magnetic elements are mounted on the gate, and the second magnetic element is mounted on the sidewall of the chamber.

10. The sputtering apparatus of claim 1, further comprising another gate, wherein the sidewall further has another opening defined therein, the another gate is provided in the another opening, the at least two first magnetic elements are four first magnetic elements, the at least one second magnetic element is two second magnetic elements, and the four first magnetic elements and the two second magnetic elements are mounted to substantially surround the rack, with two of the four first magnetic elements mounted on the gate, the other two of the four first magnetic elements mounted on the another gate, and the two second magnetic elements mounted on the sidewall of the chamber.

11. A magnetic module for a sputtering apparatus, the magnetic module comprising:
two first magnetic elements; and
a second magnetic element neighboring the two first magnetic elements;
wherein the two first magnetic elements and the second magnetic element are arranged along the arc of an imaginary circle;
a first angle is defined between two imaginary lines running from the center of the circle to a center of each of the two first magnetic elements;
a second angle is defined between an imaginary line running from the center of the circle to a center of the second magnetic element and the imaginary line running from the center of the circle to the center of one of the first magnetic elements neighboring the second magnetic element; and
the first angle and the second angle are different from each other.

12. The magnetic module of claim 11, wherein the first angle is 35° and the second angle is 45°.

13. The magnetic module of claim 11, wherein the first magnetic elements and the second magnetic element are solenoids or permanent magnets.

14. The magnetic module of claim 11, wherein the chamber is a vacuum chamber.

15. A sputtering apparatus comprising:
a chamber comprising a circumferential sidewall, the sidewall having an opening defined therein;
a rotatable rack provided in a center of the chamber;
a gate provided in the opening of the sidewall of the chamber;
two first magnetic elements mounted on the gate; and
a second magnetic element mounted inside the chamber at a periphery of the chamber;
wherein the second magnetic element neighbors one of the two first magnetic elements;
a first angle is defined between two imaginary lines running from a center axis of the rack to a center of each of the two first magnetic elements;
a second angle is defined between an imaginary line running from the center axis of the rack to a center of the second magnetic element and the imaginary line running from the center axis of the rack to the center of said one of the two first magnetic elements neighboring the second magnetic element; and
the first angle and the second angle are different from each other.

16. The sputtering apparatus of claim 15, wherein the first angle is 35° and the second angle is 45°.
